(19) United States
(12) Patent Application Publication
(10) Pub. No.: US 2014/0014839 A1
(43) Pub. Date: Jan. 16, 2014

(54) SENSOR DESIGN BASED ON LIGHT SENSING

(71) Applicants: Tom CHANG, Taipei (TW); Kao Pin WU, New Taipei (TW); Chih Jen FANG, Tainan (TW)

(72) Inventors: Tom CHANG, Taipei (TW); Kao Pin WU, New Taipei (TW); Chih Jen FANG, Tainan (TW)

(21) Appl. No.: 13/546,139

(22) Filed: Jul. 11, 2012

(51) Int. Cl. H01L 31/12

(52) U.S. Cl. 250/338.4

(57) ABSTRACT

A sensor based on light sensing is provided, including a visible light sensor, an IR sensor, an amplifier connected to visible light sensor and IR sensor, an auto-gain control (AGC) connected to amplifier, an A/D converter (ADC) connected to AGC, a digital filter connected to ADC, a multiplexer connected to both digital filter and ADC, a timing controller connected to amplifier, AGC, DC, and digital filter, a temperature sensor, a voltage reference connected to amplifier, an oscillator connected to ADC, an IR_LED driver for driving IR LEDs, a control register connected to timing controller, a data register connected to multiplexer, an I2C interface connected to external serial clock line (SCL) and serial data lines (SDA), and an interrupt interface connected to external interrupt bus (INTB). SCL, SDA and INTB are connected externally to a host able to read and display the result data from the sensor.

### FIELD OF THE INVENTION

The present invention generally relates to a sensor design based on light sensing, and more specifically to a sensor design based on light sensing with light detection circuit for ambient light sensing, proximity sensing, object presence detection and gesture recognition applications. The invention is also applicable to a host device which uses such sensor for achieving one or multiple of the functions, including ambient light sensing, proximity sensing, object presence detector, and/or gesture recognition.

### BACKGROUND OF THE INVENTION

Light sensing technologies are widely used in many applications. For example, ambient light sensors (ALS) can be used in laptop PCs and cell phones to sense the ambient lighting levels and to automatically adjust the backlight of the LCD screen to extend the battery life. Light sensors are also applied to measuring spatial distance or position. For example, proximity sensor is often found in mobile devices. Conventionally proximity sensors can be realized through different implementations, such as, inductive sensor, capacitive sensor, magnetic sensors and photoelectric sensors, wherein photoelectric sensors based on light sensing is gaining popularity. Other important applications, such as, object presence detection and gesture recognition sensing have also attracted much attention.

On the other hand, as smart devices become ubiquitous, more and more sensors are included in these smart devices to enrich the human device interaction. Therefore, a light sensor with multiple functions shows promising utility applied to the mobile devices and smart appliances.

### SUMMARY OF THE INVENTION

The primary object of the present invention is to provide a sensor design based on light sensing technologies and light detection circuit for ambient light sensing, proximity sensing, object presence detection and gesture recognition capabilities.

To achieve the objective, the present invention provides a sensor comprised of a visible light photodiode an IR photodiode, an amplifier, an auto-gain control (AGC), an A/D converter (ADC), a digital filter, a multiplexer, a timing controller, a temperature sensor, a voltage reference, an oscillator, an IR_LED driver for driving n IR LEDs, a control register, a data register, an I2C interface and an interrupt interface. Both the visible light photodiode and the IR photodiode convert the photons into the electrons. The electrons are converted into voltage by the amplifier. The timing controller sets the integration time which the amplifier is activated. The amplifier gain is programmable by shorting the feedback capacitor partially. The ADC converts the amplified analog signal into digital count out. The digital count out is sent to digital filter and compute for signal that is related to ambient light Lux level, distance or gesture. The digital filter receives outputs from ADC, and outputs to the multiplexer. The multiplexer receives outputs from ADC and digital filter, and outputs to data register. The temperature sensor is for sensing temperature and outputs to both digital filter and multiplexer. The IR driver drives n IR LEDs IR_LED0-IR_LEDn. The control register set the timing controller. The data register receives output from the multiplexer. The I2C interface is connected to serial clock line (SCL) and serial data lines (SDA). The interrupt interface outputs to interrupt bus (INTB). SCL, SDA and INTB are then all connected externally to a host.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of the sensor based on light sensing according to the invention;

FIG. 2 shows a flowchart of the operations executed by the sensor of the present invention;

FIG. 3 shows a flowchart of the ALS process executed by the sensor of the present invention;

FIG. 4 shows a flowchart of the PS process executed by the sensor of the present invention; and

FIG. 5 shows a flowchart of the OPDS/GRS process executed by the sensor of the present invention.

### DETAILED DESCRIPTION OF THE PREFERRED EMBODIMENTS

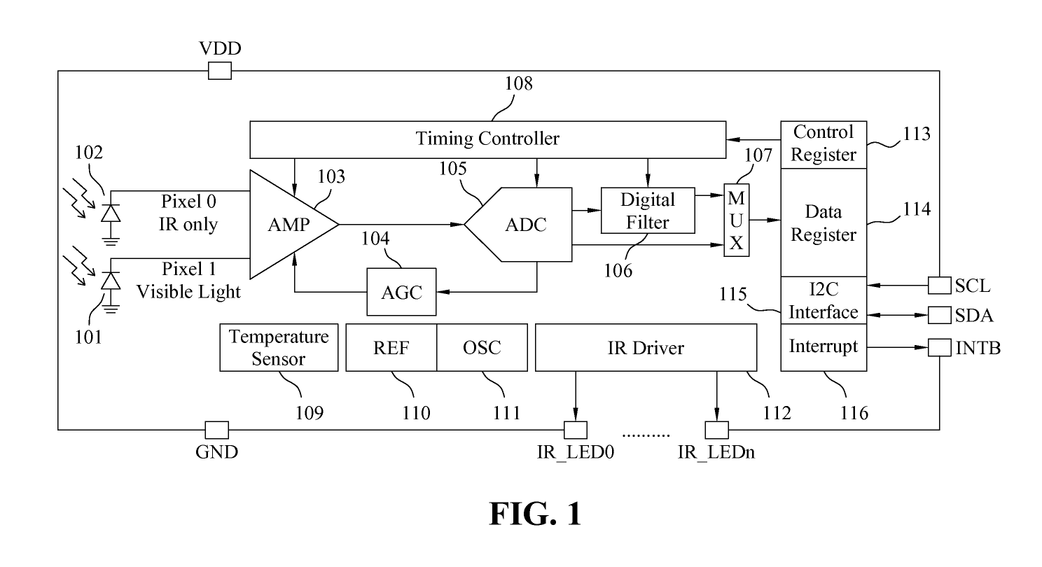

FIG. 1 shows a schematic view of a sensor based on light sensing according to the invention. As shown in FIG. 1, a sensor 100 based on light sensing, including a visible light sensor 101, an IR sensor 102, an amplifier 103, an auto-gain control (AGC) 104, an A/D converter (ADC) 105, a digital filter 106, a multiplexer 107, a timing controller 108, a temperature sensor 109, a voltage reference 110, an oscillator 111, an IR_LED driver 112 for driving n IR LEDs, labeled IR_LED0-IR_LEDn, a control register 113, a data register 114, an I2C interface 115 and an interrupt interface 116. Both visible light sensor 101 and IR sensor 102 are inputs to amplifier 103, which has timing controller 108 and AGC 104 to act as gain selector. The input of AGC 104 is connected to the output of ADC 105 and the output of AGC 104 is connected to amplifier 103. ADC 105 receives outputs from amplifier 103 and timing controller 108, and outputs to both digital filter 106 and multiplexer 107. Digital filter 106 receives outputs from timing controller 108 and ADC 105, and outputs to multiplexer 107. Multiplexer 107 receives outputs from ADC 105 and digital filter 106, and outputs to data register 114. Timing controller 108 receives output from control register 113, and outputs to amplifier 103, AGC 104, ADC 105 and digital filter 106. Temperature sensor 109 is for sensing temperature and outputs to both digital filter and multiplexer. IR driver 112 drives n IR LEDs, labeled IR_LED0-IR_LEDn. Control register 113 outputs to timing controller 108. Data register 114 receives output from multiplexer 107. I2C interface 115 is connected to serial clock line (SCL) and serial data lines (SDA). Interrupt interface 116 outputs to interrupt bus (INTB). The aforementioned SCL, SDA and INTB are connected to a host (not shown), such as, a PC or a mobile device so as to further utilize the result of the sensor of the present invention or display the measurement.

The function of each of the aforementioned elements is described as follows. Visible light sensor 101 is for receiving the visible light in the ambience, and IR sensor 102 is for receiving the IR light emitted by the IR LEDs and reflected by the object. It is worth noting that IR sensor is associated with pixel 0, and visible light sensor 101 is associated with pixel 1. Amplifier 103 translates the sensed light into analog signals and then amplifies the signal through gain selection. AGC 104 adjusts appropriate integration time and gain as the settings to the sensor operation according to the luminance of the sensed light. At least an ADC 105 is included in the present invention to convert the analog signal into digital signal, and the converted digital signal is fed to digital filter 106 for filtering and to multiplexer 107, respectively. Multiplexer 107 selects between the filtered digital signal from digital filter 106 and unfiltered digital signal from ADC 105 directly, and outputs the selected digital signal to data register 114 for storage. Timing controller 108 is responsible for the overall timing sequence control for the entire sensor. Temperature sensor 109 is for sensing the temperature, voltage reference 110 provides a bias voltage to the part of analog circuit of the sensor, and oscillator 111 is the clock source to the entire sensor. IR_LED driver 112 is for driving the n IR LEDs, labeled IR_LED0-IR_LEDn respectively. Control register 113 is for storing instruction set and data register 114 is for storing data resulted from measurement, respectively. I2C interface 115 is for transmitting and receiving instructions and data from a host machine, such as, a PC mobile device, and thus is interfacing with external serial clock line and serial data lines respectively. Interrupt interface 116 is for interrupting the aforementioned host for informing the status of the sensor. The results and measurements of light sensing by the sensor of the present invention is then further utilized and/or displayed on host.

To achieve the objectives of performing ambient light sensing (ALS), proximity sensing (PS), object position detection sensing (OPDS) and gesture recognition sensing (GRS) respectively, the sensor of the present invention operates differently. To perform ALS, the sensor uses visible light sensor 101 to sense the luminance of the visible light in the ambience. To perform PS, the sensor drives one or more IR LEDs to emit IR. The emitted is then reflected by an object and received by IR sensor 102 for further computing the proximity of the object. To perform OPDS, the sensor drives the n IR LEDs arranged on the X-Y plane to emit IR sequentially. The sequentially emitted IR is then reflected by an object and received by IR sensor 102 at different points of time. The sensed IR at different points of time is then utilized by the aforementioned host to obtain a corresponding position of the object on the X-Y plane. Similarly, to perform GRS, the sensor drives the n IR LEDs arranged in n-dimensional space to emit IR sequentially. The sequentially emitted IR is then reflected by an object and received by IR sensor 102 at different points of time. The sensed IR at different points of time is then utilized by the aforementioned host to obtain a corresponding position of the object in the n-dimensional space and determines, for example, the hand gesture. It is worth noting that because visible light sensor 101 is associated with pixel 1 while IR sensor is associated with pixel 0, ALS operation would require working with pixel 0 and pixel 1, but PS, OPDS and GRS works only with pixel 0. The details of the operation of the sensor based on light sensing are described as follows.

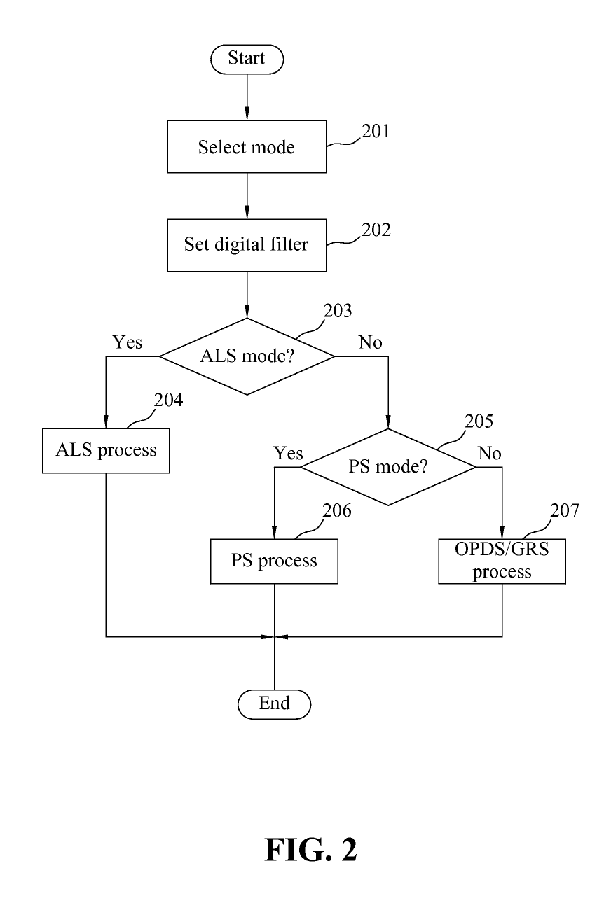

FIG. 2 shows a flow char of the detailed operations of the sensor based on light-sensing according to the present invention. As shown in FIG. 2, step 201 is to select the operation mode, namely, ALS mode, PS mode or OPDS/GRS mode. Step 202 is to set the digital filter. Step 203 is to determine whether the ALS mode has been selected, and if so, the operation proceeds to step 204 to execute ALS process; otherwise, the operation proceeds to step 205 to determine whether the PS mode has been selected, and if so, the operation processed to step 206 to execute PS process; otherwise, the operation proceeds to step 207 to execute OPDS/GRS process. The operation ends after executing prospect ALS process, PS process or OPDS/GRS process according to the selected mode.

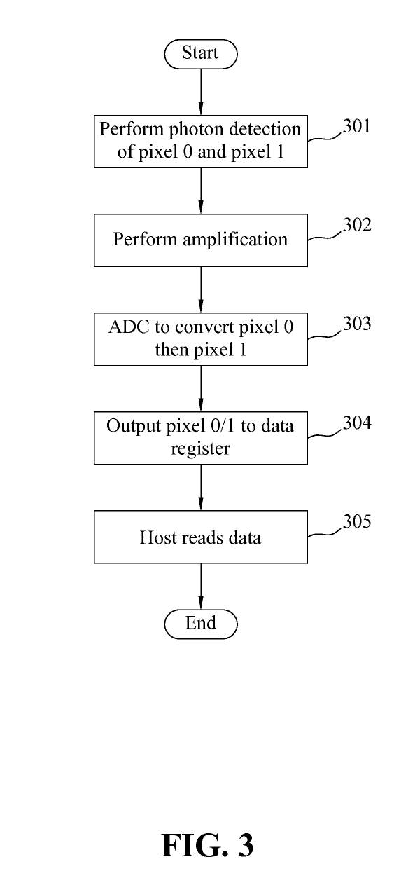

FIG. 3 shows a flowchart of the ALS process executed by the sensor of the present invention. As shown in FIG. 3, step 301 is to perform photon detection with both pixel 0 and pixel 1. In Step 302, the detected pixel 0 and pixel 1 are amplified through amplifier 103 and/or AGC 104. The integral time and the gain determine the amplification to transform the sensed light into a voltage. Step 303 is for ADC 105 to convert the signal of pixel 0 into digital signal, and then convert the signal of pixel 1 into digital signal, too. Step 304 is to output the pixel 0/1 data to data register 114. In step 305, the host reads and displays the data through I2C interface 115.

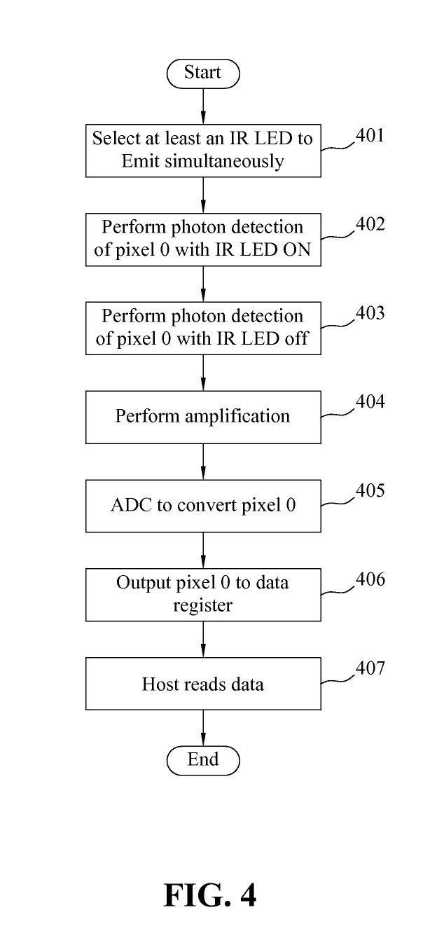

FIG. 4 shows a flowchart of the PS process executed by the sensor of the present invention. As shown in FIG. 4, step 401 is to select at least an IR LED from the n IR LEDs and drive the selected IR LEDs to emit simultaneously. Step 402 is to perform photon detection of pixel 0 with the selected IR LEDs on. Step 403 is to perform photon detection of pixel 0 with the selected IR LEDs off. In Step 404, the detected pixel 0 is amplified through amplifier 103 and/or AGC 104. The integral time and the gain determine the amplification to transform the sensed light into a voltage. Step 405 is for ADC 105 to convert the signal of pixel 0 into digital signal. Step 406 is to output the pixel 0 data to data register 114. In step 407, the host reads and displays the data through I2C interface 115.

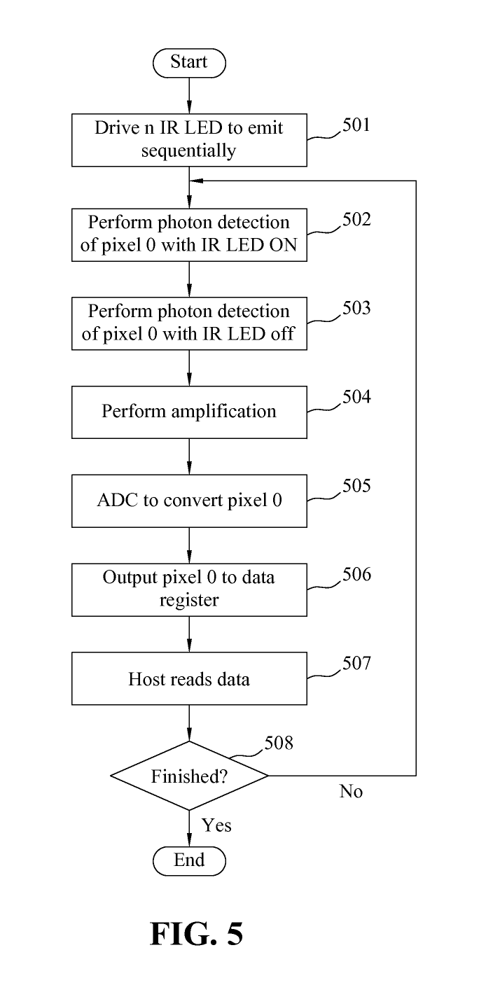

FIG. 5 shows a flowchart of the OPDS/GRS process executed by the sensor of the present invention. The OPDS/GRS process is similar to the above PS process, except that the steps are executed with each of the n IR LEDs emitting IR sequentially. As shown in FIG. 5, step 501 is to drive each of the n IR LEDs to emit simultaneously and execute the following steps for each emitting IR LED. Step 502 is to perform photon detection of pixel 0 with the selected IR LEDs on. Step 503 is to perform photon detection of pixel 0 with the selected IR LEDs off. In Step 504, the detected pixel 0 is amplified through amplifier 103 and/or AGC 104. The integral time and the gain determine the amplification to transform the sensed light into a voltage. Step 505 is for ADC 105 to convert the signal of pixel 0 into digital signal. Step 506 is to output the pixel 0 data to data register 114. In step 507, the host reads and displays the data through I2C interface 115. Step 508 is to determine whether finishing all the n IR LEDs, and if so, the process terminates; otherwise, the process returns to step 502.

It is worth noting that in ALS, PS and OPDS/GRS processes, the result is written to the data register, and an interrupt can be sent to the host so that the host can read data from the data register through the SDA lines. The sensor can also define a threshold, and sends the interrupt signal to the host only when the result exceeds the defined threshold.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A sensor, sensor IC, sensor module, or sensing sensor based on light sensing technology, applicable for ambient light sensing, proximity sensing, object position sensing and gesture recognition application, said sensor comprising:
a visible light photodiode, an IR photodiode, more than one IR_LED drivers for driving n IR LEDs.

2. The sensor based on light sensing as claimed in claim 1, wherein said visible light photodiode is for sensing visible light in ambience and said IR photodiode is for sensing IR light in ambience and the reflected IR light from the emitted light by said n IR LEDs.

3. The sensor based on light sensing as claimed in claim 1, wherein in said proximity sensing application, at least an IR LED from said n IR LEDs is turned on to emit light while the IR photodiode and amplifier is integrating simultaneously.

4. The sensor based on light sensing as claimed in claim 1, wherein in said object position sensing application, said n IR LEDs are arranged in X-Y plane and said n IR LEDs are turned on to emit light in a sequential order.

5. The sensor based on light sensing as claimed in claim 1, wherein in said gesture recognition application, said n IR LEDs are arranged to define a three-dimensional space and said n IR LEDs are turned on to emit light in a sequential order, where the output signals are tracked with the respective IR LEDs.

6. The sensor based on light sensing as claimed in claim 1, wherein said amplifier and said AGC use integration time and gain to determine amplification and to transform sensed light into a voltage.

7. The sensor based on light sensing as claimed in claim 1, wherein said sensor defines a threshold and when said light sensing result exceeds said threshold, said sensor sends an interrupt to said host.
